(19) United States
(12) Patent Application Publication
(10) Pub. No.: US 2017/0097868 A1
(43) Pub. Date: Apr. 6, 2017

(54) DATA STORAGE DEVICE AND OPERATING METHOD THEREOF

(71) Applicant: SK hynix Inc., Gyeonggi-do (KR)

(72) Inventors: Kyung Bum KIM, Gyeonggi-do (KR); Won Tak BAE, Gyeonggi-do (KR)

(21) Appl. No.: 15/071,943

(22) Filed: Mar. 16, 2016

(30) Foreign Application Priority Data
Oct. 1, 2015 (KR) 10-2015-0138539

(51) Int. Cl. G06F 11/10; G11C 29/52; G11C 7/00

(52) U.S. Cl. CPC G06F 11/1068; G11C 7/00; G11C 29/52

(57) ABSTRACT

A data storage device includes a controller; and a nonvolatile memory device comprising a memory region including a plurality of memory cells, the nonvolatile memory device being suitable for acquiring first data by applying a first read voltage to the plurality of memory cells and acquiring second data by applying a plurality of second read voltages to the plurality of memory cells, according to control of the controller, wherein the controller is suitable for performing an error correction operation for the first data, based on the second data, and wherein the plurality of second read voltages have nonlinear variation rates with respect to the first read voltage.

### CROSS-REFERENCES TO RELATED APPLICATION

The present application claims priority under 35 U.S.C. §119(a) to Korean application number 10-2015-0138539, filed on Oct. 1, 2015, in the Korean Intellectual Property Office, which is incorporated herein by reference in its entirety.

### BACKGROUND

1. Technical Field

Various embodiments of the invention relate generally to a data storage device and, more particularly, to a data storage device capable of performing an error correction operation.

2. Related Art

Data storage devices store data provided by an external device in response to a write request. Data storage devices may also provide stored data to an external device in response to a read request. Examples of external devices that use data storage devices include computers, digital cameras, cellular phones and the like. Data storage devices can be embedded in external devices or fabricated separately and then connected afterwards.

### SUMMARY

An aspect of the present invention is directed to, a data storage device including: a controller; and a nonvolatile memory device comprising a memory region including a plurality of memory cells, the nonvolatile memory device being suitable for acquiring first data by applying a first read voltage to the plurality of memory cells and acquiring second data by applying a plurality of second read voltages to the plurality of memory cells, according to control of the controller, wherein the controller is suitable for performing an error correction operation for the first data, based on the second data, and wherein the plurality of second read voltages have nonlinear variation rates with respect to the first read voltage.

Another aspect of the present invention is directed to a method for operating a data storage device, the method including: acquiring first data by applying a first read voltage to memory cells; acquiring second data by applying a plurality of second read voltages to the memory cells; and performing an error correction operation for the first data based on the second data, wherein the plurality of second read voltages have variation rates that are nonlinear with respect to the first read voltage.

### BRIEF DESCRIPTION OF THE DRAWINGS

FIG. 1 is a block diagram illustrating a data storage device, according to an embodiment of the invention.

FIG. 2 is a block diagram illustrating an example of a detailed configuration of the nonvolatile memory device shown in FIG. 1.

FIG. 3 is an example of a graph illustrating initial threshold voltage distributions and varied threshold voltage distributions of memory cells.

FIG. 4 is an example of a graph illustrating a method for acquiring soft decision data from memory cells and mapping LLR (log likelihood ratio) values to the soft decision data.

FIG. 5 is an example of a graph illustrating a method for acquiring new soft decision data from memory cells by using adjusted soft read voltages.

FIG. 6 is a flow chart illustrating a method for operating the data storage device of FIG. 1, according to an embodiment of the invention.

FIG. 7 is a flow illustrating a method for operating the data storage device of FIG. 1, according to an embodiment of the invention.

FIG. 8 is a block diagram illustrating a solid state drive (SSD), according to an embodiment of the invention.

FIG. 9 is a block diagram illustrating a data processing system including the data storage device of FIG. 1, according to an embodiment of the invention.

### DETAILED DESCRIPTION

Hereinafter, a data storage device and an operating method thereof according to the present invention will be described with reference to the accompanying drawings through exemplary embodiments of the present invention. The present invention may, however, be embodied in different forms and should not be construed as being limited to the embodiments set forth herein. Rather, these embodiments are provided to describe the present invention in detail to the extent that a person skilled in the art to which the invention pertains can practice the present invention.

It is to be understood that embodiments of the present invention are not limited to the particulars shown in the drawings, that the drawings are not necessarily to scale, and, in some instances, proportions may have been exaggerated in order to more clearly depict certain features of the invention. While particular terminology is used, it is to be appreciated that the terminology used is for describing particular embodiments only and is not intended to limit the scope of the present invention.

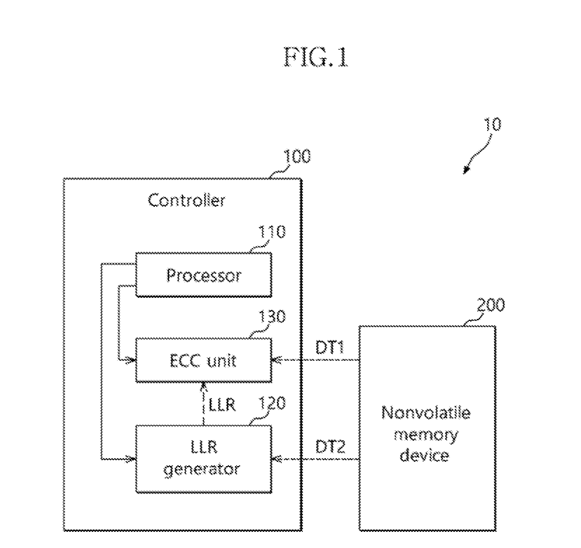

FIG. 1 is a block diagram illustrating a data storage device 10, according to an embodiment of the invention.

The data storage device 10 may be configured to store data provided from an external device, in response to a write request from the external device. Also, the data storage device 10 may be configured to provide stored data to the external device, in response to a read request from the external device.

The data storage device 10 may be configured by a Personal Computer Memory Card International Association (PCMCIA) card, a compact flash (CF) card, a smart media card, a memory stick, a multimedia card in the form of MMC, eMMC, RS-MMC and MMC-micro, a secure digital card in the form of SD, mini-SD and micro-SD, a universal flash storage (UFS), a solid state drive (SSD) and the like.

The data storage device 10 may include a controller 100 and a nonvolatile memory device 200.

The controller 100 may include a processor 110, a log likelihood ratio (LLR) generator 120, and an error correction code (ECC) unit 130.

The processor 110 may control the general operations of the data storage device 10. The processor 110 may store data in the nonvolatile memory device 200 in response to a write request transmitted from an external device, and may read data stored in the nonvolatile memory device 200 and output the read data to the external device in response to a read request transmitted from the external device.

The processor 110 may control the nonvolatile memory device 200 to acquire first data DT1 and second data DT2. As will be described later in detail, the first data DT1 may be hard decision data, and the second data DT2 may be soft decision data. The processor 110 may control the nonvolatile memory device 200 to set a hard read voltage to acquire the first data DT1. The processor 110 may control the nonvolatile memory device 200 to set a plurality of soft read voltages to acquire the second data DT2. The plurality of soft read voltages may have variable rates with respect to the hard read voltage. The plurality of soft read voltages may have linear variation rates with respect to the hard read voltage. Preferably, the plurality of soft read voltages may have nonlinear variation rates with respect to the hard read voltage.

The processor 110 may control the LLR generator 120 to generate LLR values based on the second data DT2. The processor 110 may control the ECC unit 130 to perform an error correction operation for the first data DT1 based on the LLR values.

According to an embodiment, the processor 110 may control the ECC unit 130 to perform a pre-error correction operation for the first data DT1 before performing the error correction operation based on the second data DT2. The pre-error correction operation may be performed without using the second data DT2. When the pre-error correction operation has failed, the processor 110 may control the ECC unit 130 to perform the error correction operation for the first data DT1, based on the second data DT2. The pre-error correction operation may be performed in a decoding scheme different from the error correction operation.

The LLR generator 120 may generate the LLR values corresponding to the second data DT2. The LLR values may respectively correspond to memory cells from which the second data DT2 are acquired. The LLR generator 120 may generate the LLR values, for example, by referring to a table in which patterns of second data DT2 and LLR values are mapped. While it is illustrated in FIG. 1 that the LLR generator 120 is independent of the processor 110 and the ECC unit 130, it is to be noted that, according to an embodiment, the LLR generator 120 may be included in the processor 110 or the ECC unit 130.

The ECC unit 130 may perform the error correction operation by determining whether an error bit has occurred in data read from the nonvolatile memory device 200 and by decoding the corresponding data when an error bit has occurred. The ECC unit 130 may perform the error correction operation for the first data DT1, based on the LLR values generated by the LLR generator 120. The ECC unit 130 may perform the error correction operation for the first data DT1, for example, in a soft decision decoding scheme.

According to an embodiment, before performing the error correction operation for the first data DT1 based on the LLR values, the ECC unit 130 may perform the pre-error correction operation for the first data DT1, according to control of the processor 110. The ECC unit 130 may perform the pre-error correction operation for the first data DT1, for example, in a hard decision decoding scheme. The ECC unit 130 may report a correction failure to the processor 110 when the pre-error correction operation has failed. When the pre-error correction operation has failed, the ECC unit 130 may perform the error correction operation for the first data DT1, based on the LLR values, according to control of the processor 110.

The ECC unit 130 may operate according to, for example, an low density parity check (LDPC) algorithm. The ECC unit 130 may process data by a predetermined data chunk unit.

The nonvolatile memory device 200 may include flash memory devices such as NAND flash or NOR flash, Ferroelectrics Random Access Memory (FeRAM), Phase-Change Random Access Memory (PCRAM), Magnetoresistive Random Access Memory (MRAM) or Resistive Random Access Memory (ReRAM).

The nonvolatile memory device 200 may store data transmitted from the controller 100 and may read stored data and transmit read data to the controller 100, according to control of the controller 100. The nonvolatile memory device 200 may acquire the first data DT1 and the second data DT2 and transmit them to the controller 100, according to control of the controller 100.

While it is illustrated in FIG. 1 that the data storage device includes one nonvolatile memory device 200, it is to be noted that the number of nonvolatile memory devices included in the data storage device 10 is not specifically limited.

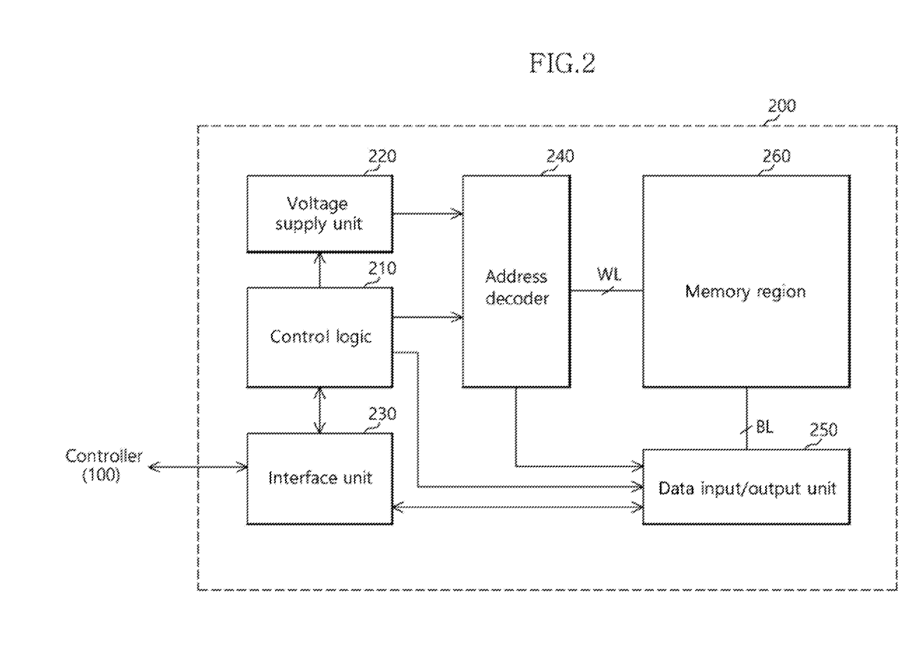

FIG. 2 is a block diagram illustrating a representation of an example of the detailed configuration of the nonvolatile memory device 200 shown in FIG. 1.

The nonvolatile memory device 200 may include a control logic 210, a voltage supply unit 220, an interface unit 230, an address decoder 240, a data input/output unit 250, and a memory region 260.

The control logic 210 may control general operations of the nonvolatile memory device 200 according to control of the controller 100. The control logic 210 may control internal units of the nonvolatile memory device 200 to acquire the first data DT1 and the second data DT2 from memory cells of the memory region 260, according to control of the controller 100.

The voltage supply unit 220 may generate various operation voltages necessary for general operations of the nonvolatile memory device 200, according to control of the control logic 210. For example, the voltage supply unit 220 may supply various read voltages to be used in operations which will be described later, to the address decoder 240.

The Interface unit 230 may exchange various control signals including commands and addresses and data with the controller 100.

The interface unit 230 may transmit various control signals and data inputted thereto, to internal units of the nonvolatile memory device 200. The Interface unit 230 may transmit the first data DT1 and the second data DT2 transmitted from the data input/output unit 250, to the controller 100.

The address decoder 240 may decode addresses to select portions to be accessed in the memory region 260. The address decoder 240 may selectively drive word lines WL and control the data input/output unit 250 to selectively drive bit lines BL, according to decoding results. The address decoder 240 may apply a predetermined read voltage to a selected word line which are coupled with memory cells, according to control of the control logic 210.

The data input/output unit 250 may transmit data transmitted from the Interface unit 230, to the memory region 260 through the bit lines BL. The data input/output unit 250 may transmit data read from the memory region 260 through the bit lines BL, to the interface unit 230. The data input/output unit 250 may sense current formed as memory cells are turned on and off in response to the read voltage, and may acquire data corresponding to the memory cells, according to sensing results. The data input/output unit 250 may transmit the acquired data as the first data DT1 and the second data DT2, to the interface unit 230.

The memory region 260 may be coupled with the address decoder 240 through the word lines WL, and may be coupled with the data input/output unit 250 through the bit lines BL. The memory region 260 may include a plurality of memory cells which are respectively disposed at areas where the word lines WL and the bit lines BL cross each other and in which data are stored. The memory region 260 may include memory cell arrays of a two-dimensional or three-dimensional structure.

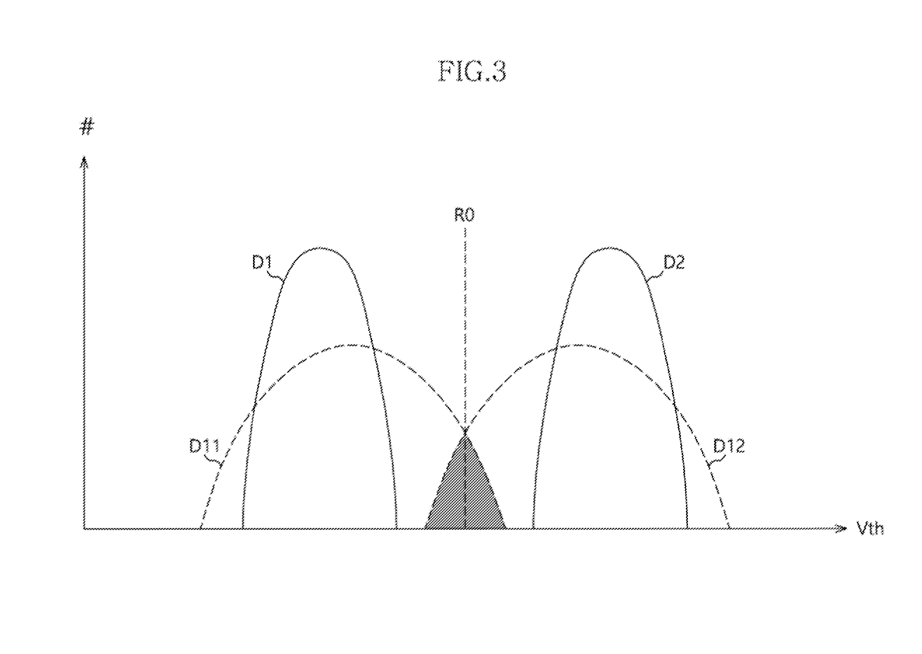

FIG. 3 is a graph showing initial threshold voltage distributions D1 and D2 and varied threshold voltage distributions D11 and D12 of memory cells. In the graph of FIG. 3, the horizontal axis Vth denotes a threshold voltage of a memory cell, whereas the vertical axis # denotes the number of memory cells.

Memory cells may form the threshold voltage distributions D1 and D2 according to data stored therein through a write operation. For example, memory cells stored with data “1” may form the threshold voltage distribution D1, and memory cells stored with data “0” may form the threshold voltage distribution D2. When the write operation is performed, memory cells may be controlled to form the threshold voltage distributions D1 and D2 according to data to be stored therein.

A memory cell stored with data may be turned on or off according to a threshold voltage thereof in response to a predetermined read voltage R0. As the memory cell is turned on or off, the memory cell may form a certain amount of current. As the formed current is sensed, data corresponding to the memory cell may be acquired. Acquired data may be different according to a read voltage applied to a memory cell.

In detail, a memory cell which forms the threshold voltage distribution D1 may be turned on when the read voltage R0 higher than its threshold voltage is applied thereto, and a memory cell which forms the threshold voltage distribution D2 may be turned off when the read voltage R0 lower than its threshold voltage is applied thereto. Data “1” may be acquired from a turned-on memory cell, and data “0” may be acquired from a turned-off memory cell.

At least one read voltage, like the read voltage R0, for identifying a plurality of threshold voltage distributions, that is, for determining data stored in memory cells, may be a hard read voltage. Hard decision data may be acquired based on data acquired as a hard read voltage is applied to memory cells. Hard decision data may mean data stored in memory cells.

When 1 bit is stored in each memory cell and memory cells form the threshold voltage distributions D1 and D2, data acquired as the read voltage R0 is applied to the memory cells may be actually acquired as hard decision data. When k bits are stored in each memory cell and memory cells form 2̂k number of threshold voltage distributions according to data stored therein, hard decision data may be acquired based on calculation of data values acquired as 2̂k−1 number of read voltages for identifying the 2̂k number of threshold voltage distributions are respectively applied to the memory cells.

Meanwhile, threshold voltages of memory cells may vary due to various reasons. When threshold voltages of memory cells vary, the threshold voltage distributions D1 and D2 may be respectively changed to the threshold voltage distributions D11 and D12. With respect to the read voltage R0, data values acquired from memory cells included in the shaded portion of FIG. 3 may be different from those before threshold voltages vary. As a result, hard decision data acquired from memory cells having threshold voltages which have been varied may include an error bit.

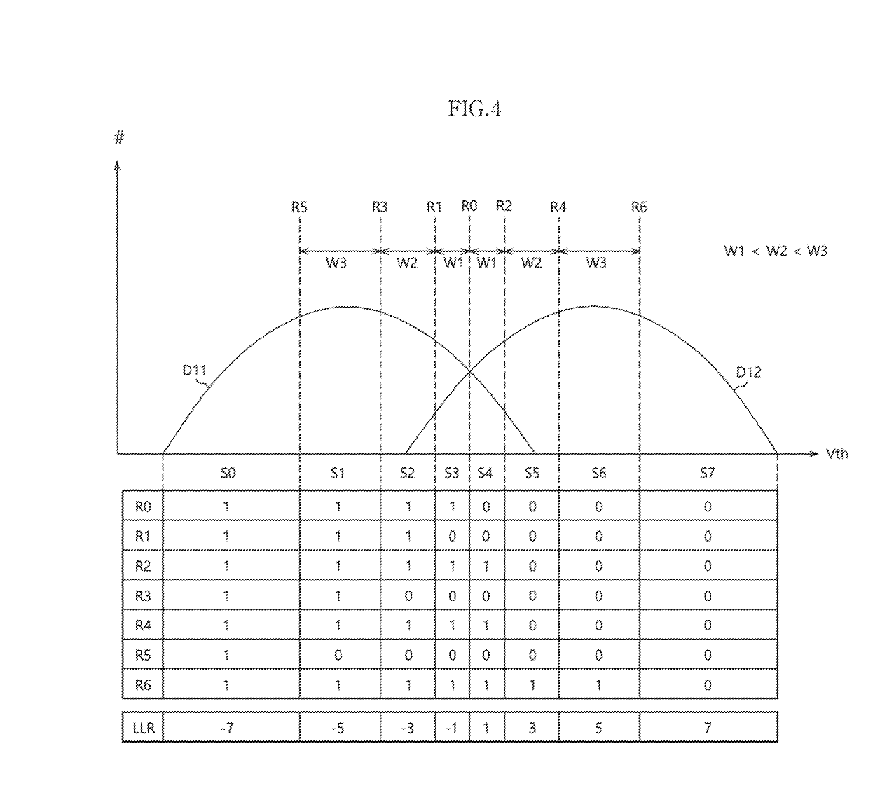

FIG. 4 is a representation of an example of a graph to assist in the explanation of a method for acquiring soft decision data from memory cells and mapping LLR values to the soft decision data. In the graph of FIG. 4, the horizontal axis Vth denotes a threshold voltage of a memory cell, and the vertical axis # denotes the number of memory cells.

Soft decision data may include data values acquired from memory cells as a plurality of soft read voltages R1 to R6 are applied to the memory cells. Soft decision data may be used to afford reliability to hard decision data acquired from memory cells. As will be described below, soft decision data may be used by the LLR generator 120 to generate LLR values.

In order to acquire soft decision data, the soft read voltages R1 to R6 used in addition to the hard read voltage R0 may have nonlinear variation rates with respect to the hard read voltage R0. Variation rates of the soft read voltages R1, R3 and R5 with respect to the hard read voltage R0 may have negative values that decrease nonlinearly, and variation rates of the soft read voltages R2, R4 and R6 with respect to the hard read voltage R0 may have positive values that increase nonlinearly. Accordingly, the read voltages R0 to R6 may form irregular intervals on the threshold voltage axis Vth. Intervals between the soft read voltages R1 to R6 on the threshold voltage axis Vth may gradually decrease toward the hard read voltage R0. For example, an interval W1 between the read voltages R1 and R0 may be shorter than an interval W2 between the read voltages R3 and R1 which may be shorter than an interval W3 between the read voltages R3 and R5.

Meanwhile, FIG. 4 illustrates that intervals between the read voltages R0 to R6 are bilaterally symmetrical with respect to the hard read voltage R0. According to an embodiment, intervals between the read voltages R0 to R6 may be asymmetrical with respect to the hard read voltage R0.

The read voltages R0 to R6 may define preset intervals S0 to S7 on the threshold voltage axis Vth. Memory cells positioned in the same interval may correspond, in the same manner, to soft decision data arranged in the column direction in the table of FIG. 4. For example, soft decision data “1111111” may be acquired from memory cells positioned in the interval S0, soft decision data “1011111” may be acquired from memory cells positioned in the interval S1, and soft decision data “1010111” may be acquired from memory cells positioned in the interval S2.

In detail, in order to acquire soft decision data, the respective read voltages R0 to R6 may be applied to memory cells.

For example, when the respective read voltages R0 to R6 are applied, memory cells positioned in the interval S0 may be always turned on, and accordingly, “1”s may be acquired from the memory cells for the read voltages R0 to R6. For example, memory cells positioned in the interval S1 may be turned off only when the read voltage R5 is applied, and accordingly, “0” may be acquired from the memory cells for the read voltage R5 and “1”s may be acquired from memory cells for the read voltages R1 to R4 and R6.

According to an embodiment, if hard decision data acquired from memory cells for the hard read voltage R0 exist to perform the pre-error correction operation, applying the read voltage R0 to memory cells may be omitted when acquiring soft decision data.

According to an embodiment, soft decision data may be acquired by using soft read voltages the number of which is different from the number of the soft read voltages R1 to R6 of FIG. 4. The number of soft read voltages for acquiring soft decision data may determine the number of intervals divided on the threshold voltage axis Vth and the size of soft decision data.

The LLR generator 120 may generate an LLR value corresponding to soft decision data. The LLR generator 120 may generate an LLR value corresponding to soft decision data, for example, by referring to a table in which patterns of soft decision data and LLR values are mapped.

An LLR value may be generated based on a ratio of the probability of data stored in memory cells to be “1” and a ratio of the probability of the data stored in the memory cells to be “0.” An LLR value may be generated as, for example, a negative number that has a larger absolute value, as the probability of data stored in memory cells to be “1” increases. An LLR value may be generated as, for example, a positive number that has a larger absolute value, as the probability of data stored in memory cells to be “0” increases. An LLR value may mean reliability for hard decision data.

That is to say, since soft decision data corresponds to a specific interval, an interval in which memory cells are positioned may be specified on the thresh voltage axis Vth based on soft decision data acquired from the corresponding memory cells. Further, since a probability of hard decision data to include an error bit is different in respective intervals, adequate reliability may be afforded to hard decision data according to an interval. In other words, for example, hard decision data acquired from a memory cell positioned in the interval S0 or the interval S7 may have a high probability not to be an error bit. Accordingly, an LLR value having a large absolute value meaning high reliability may correspond to the hard decision data. Moreover, for example, hard decision data acquired from a memory cell positioned in the interval S3 or the interval S4 may have a high probability to be an error bit. Accordingly, an LLR value having a small absolute value meaning low reliability may correspond to the hard decision data.

According to the embodiment, since intervals between soft read voltages on the threshold voltage axis Vth decrease as they are closer to a hard read voltage, memory cells having a high probability of an error bit to occur, for example, the memory cells positioned in the shaded portion of FIG. 3 may be finely allocated with LLR values. As a consequence, a success rate of the error correction operation by the soft decision decoding scheme may be increased, and data reliability of the data storage device 10 may be improved.

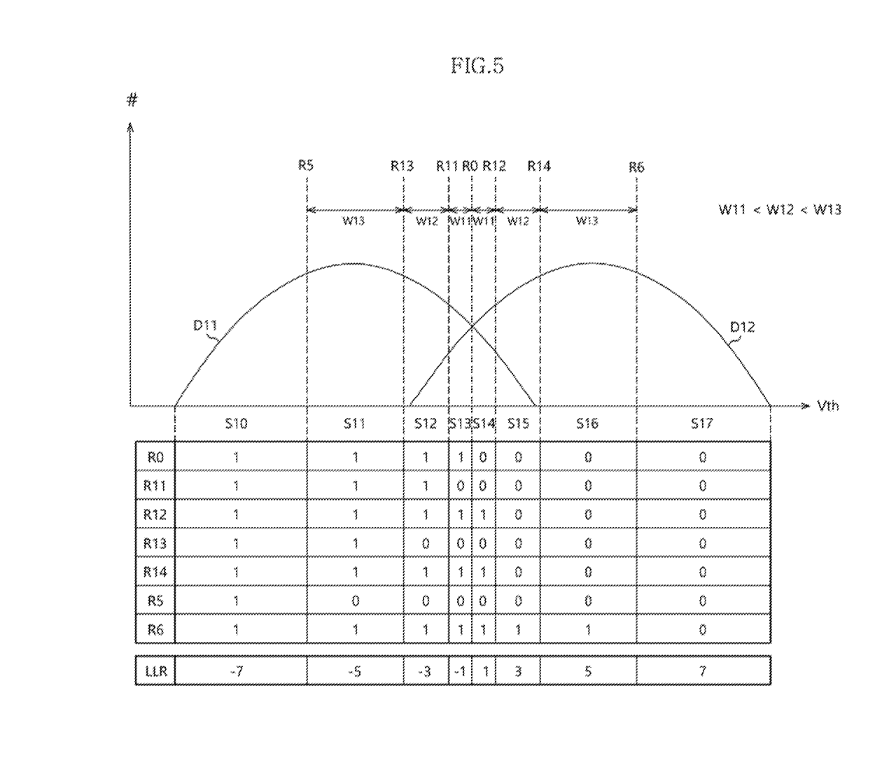

FIG. 5 is a representation of an example of a graph to assist in the explanation of a method for acquiring new soft decision data from memory cells by using adjusted soft read voltages R1 to R14.

When the error correction operation by the soft decision decoding scheme has failed, for example, the soft read voltages R1 to R4 among the soft read voltages R1 to R6 are adjusted. As adjusted soft read voltages R11 to R14 are applied to corresponding memory cells, new soft decision data may be acquired. That is to say, intervals S10 to S17 may be newly defined on the threshold voltage axis Vth due to the adjusted soft read voltages R11 to R14, and memory cells belonging to intervals different from those before the adjustment may correspond to new soft decision data. The controller 100 may perform again the error correction operation for hard decision data, based on the new soft decision data.

On the threshold voltage axis Vth, Intervals between the adjusted soft read voltages R11 to R14 may be more finely defined near the hard read voltage R0 than in the previous case. For example, the soft read voltages R1 to R4 of FIG. 4 may be adjusted to the soft read voltages R11 to R14 to be closer to the hard read voltage R0. For example, an adjusted interval W11 between the adjusted soft read voltage R11 and the hard read voltage R0 may be shorter than the interval W1 between the soft read voltage R1 of FIG. 4 and the hard read voltage R0. The adjusted soft read voltages R11 to R14 may still have nonlinear variation rates with respect to the hard read voltage R0.

According to an embodiment, performing again the error correction operation by adjusting soft read voltages may be iterated within a maximum adjustment count. When the error correction operation has failed even though the error correction operation was iterated up to the maximum adjustment count by adjusting soft read voltages, the controller 100 may not perform any more and end the error correction operation.

While FIG. 5 illustrates the case where some soft read voltages R11 to R14 are adjusted among the soft read voltages R1 to R6 of FIG. 4, it is to be noted that the number of adjusted soft read voltages is not specifically limited.

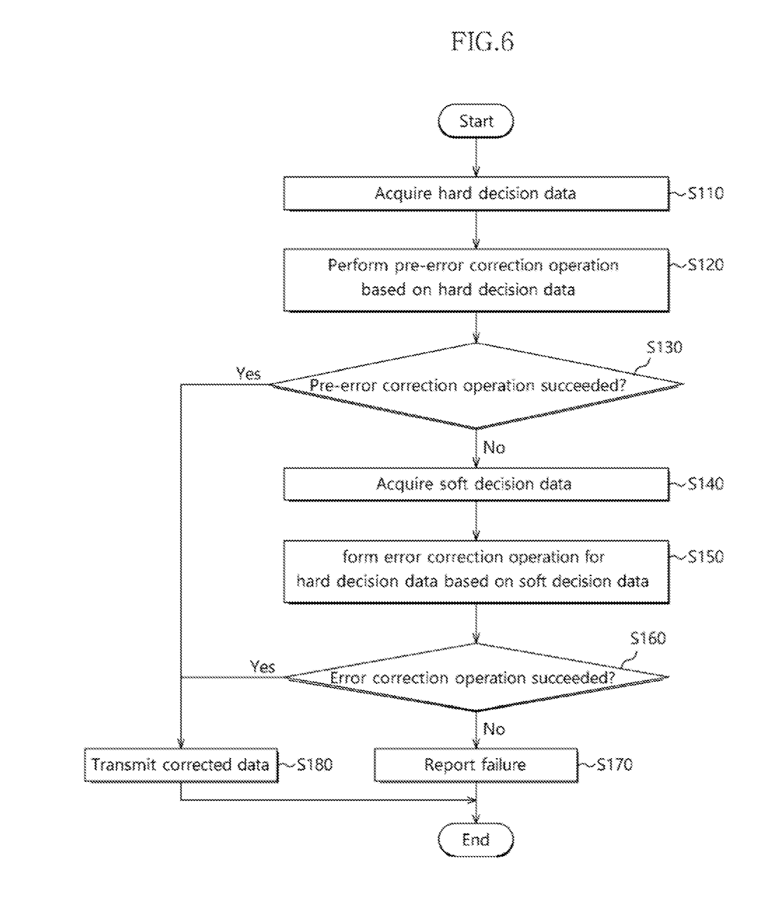

FIG. 6 is a representation of an example of a flow chart to assist in the explanation of a method for operating the data storage device 10 of FIG. 1. FIG. 6 shows an operating method for the controller 100 to read data stored in memory cells of the nonvolatile memory device 200, in response to, for example, a read request from an external device.

At step S110, the nonvolatile memory device 200 may acquire hard decision data from memory cells according to control of the controller 100. The nonvolatile memory device 200 may apply a hard read voltage to the memory cells to acquire the hard decision data. The hard decision data may be transmitted to the controller 100.

At step S120, the controller 100 may perform a pre-error correction operation for the hard decision data. When performing the pre-error correction operation, the controller 100 may decode the hard decision data in a hard decision decoding scheme.

At step S130, the controller 100 may determine whether the pre-error correction operation has succeeded. When it is determined that the pre-error correction operation has succeeded, the process may proceed to step S180. At the step S180, the controller 100 may transmit corrected data to the external device.

When it is determined at the step S130 that the pre-error correction operation has failed, the process may proceed to step S140. At the step S140, the nonvolatile memory device 200 may acquire soft decision data from the memory cells according to control of the controller 100. The nonvolatile memory device 200 may apply a plurality of soft read voltages to the memory cells to acquire the soft decision data. The soft read voltages may have nonlinear variation rates with respect to the hard read voltage. The soft read voltages may have variation rates that nonlinearly increase or decrease with respect to the hard read voltage. The controller 100 may provide a plurality of offsets respectively corresponding to the variation rates, to the nonvolatile memory device 200. The nonvolatile memory device 200 may set the soft read voltages based on the plurality of offsets. The acquired soft decision data may be transmitted to the controller 100.

At step S150, the controller 100 may perform an error correction operation for the hard decision data, based on the soft decision data. When performing the error correction operation, the controller 100 may generate LLR values corresponding to the soft decision data, and decode the hard decision data in a soft decision decoding scheme.

At step S160, the controller 100 may determine whether the error correction operation has succeeded. When it is determined that the error correction operation has succeeded, the process may proceed to the step S180. When it is determined that the error correction operation has failed, the process may proceed to step S170.

At the step S170, the controller 100 may report the failure of the error correction operation to the external device.

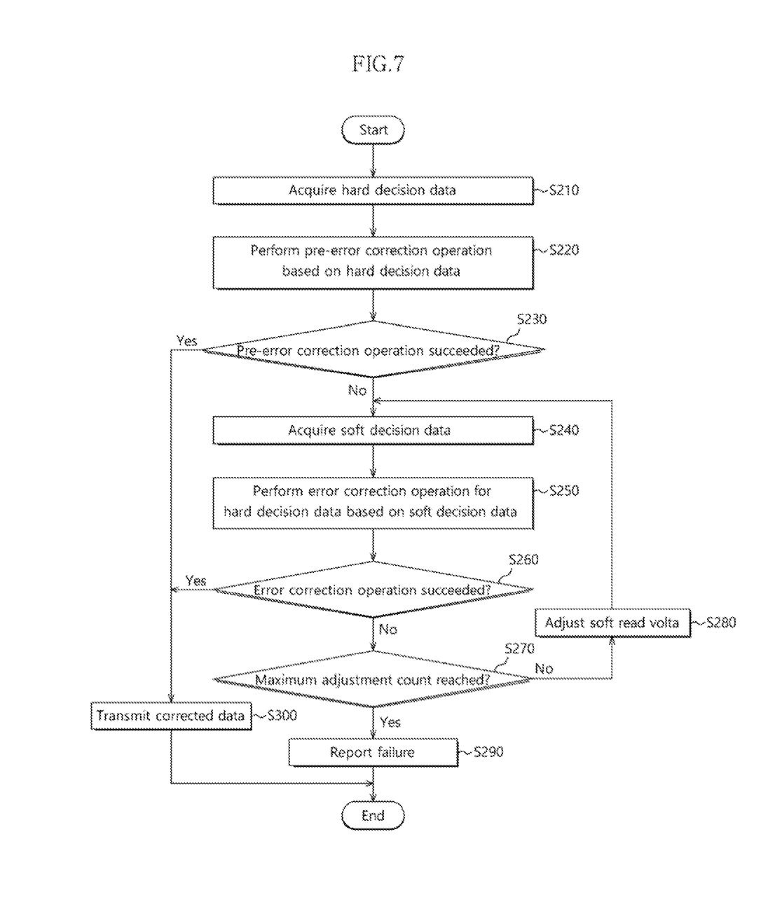

FIG. 7 is a representation of an example of a flow chart to assist in the explanation of a method for operating the data storage device 10 of FIG. 1. FIG. 7 shows an operating method for the controller 100 to read data stored in memory cells of the nonvolatile memory device 200, in response to, for example, a read request from an external device.

Step S210 to step S250 and step S300 may be substantially similar to the step S110 to the step S150 and the step S180 of FIG. 6.

At step S260, the controller 100 may determine whether the error correction operation has succeeded. When it is determined that the error correction operation has succeeded, the process may proceed to the step S300. When it is determined that the error correction operation has failed, the process may proceed to step S270.

At step S270, the controller 100 may determine whether a count of times of adjusting soft read voltages has reached a maximum adjustment count. When it is determined that a count of times of adjusting soft read voltages has reached the maximum adjustment count, the process may proceed to step S290. When it is determined that a count of times of adjusting soft read voltages has not reached the maximum adjustment count, the process may proceed to step S280.

At step S280, the controller 100 may adjust the soft read voltages. On a threshold voltage axis Vth, intervals between adjusted soft read voltages may be more fine near the hard read voltage than the previous case. At the step S240, the nonvolatile memory device 200 may acquire soft decision data by applying adjusted soft read voltages to the memory cells according to control of the controller 100. In other words, the controller 100 may iterate the error correction operation by adjusting soft read voltages within the maximum adjustment count until the error correction operation succeeds.

At the step S290, the controller 100 may report the failure of the error correction operation to the external device.

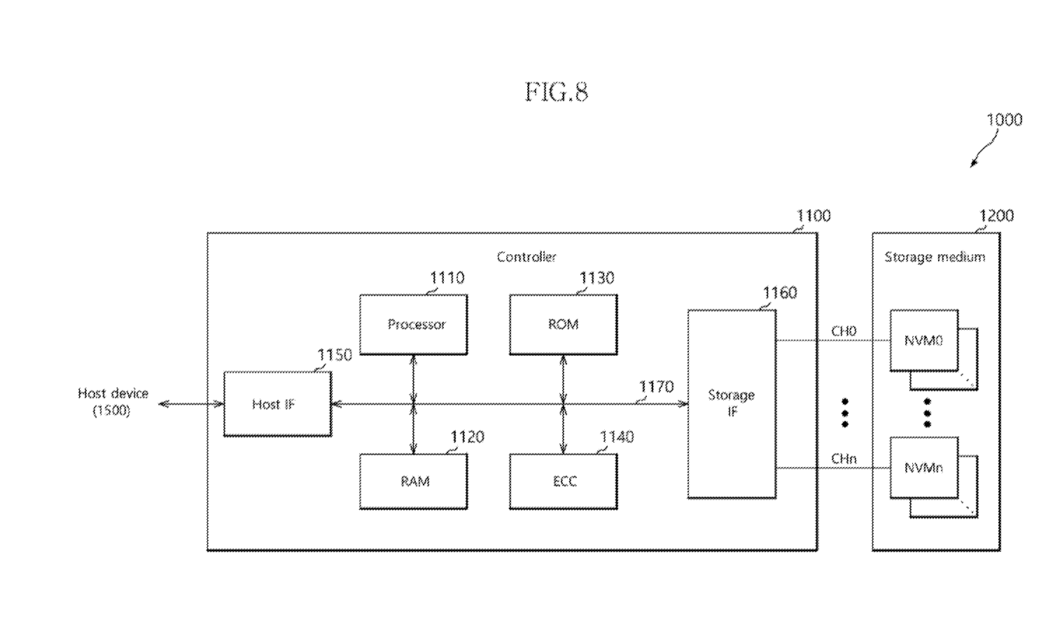

FIG. 8 is a block diagram illustrating a representation of an example of a solid state drive (SSD) 1000 according to an embodiment of the invention.

The SSD 1000 may include a controller 1100 and a storage medium 1200.

The controller 1100 may control data exchange between the host device 1500 and the storage medium 1200. The controller 1100 may include a processor 1110, a RAM 1120, a ROM 1130, an ECC unit 1140, a host interface 1150, and a storage medium interface 1160.

The processor 1110 may control the general operations of the controller 1100. The processor 1110 may store data in the storage medium 1200 and read stored data from the storage medium 1200, according to data processing requests from the host device 1500. In order to efficiently manage the storage medium 1200, the processor 1110 may control the internal operations of the SSD 1000 such as a merge operation, a wear leveling operation, and so forth.

Also, the processor 1110 may be configured in a manner substantially similar to the processor 110 shown in FIG. 1. The processor 1110 may control the storage medium 1200 to acquire hard decision data DT1 and soft decision data from a memory region of the storage medium 1200. In order to acquire soft decision data DT2, the processor 1110 may control the storage medium 1200 to set a plurality of soft read voltages which have nonlinear variation rates with respect to a hard read voltage.

The RAM 1120 may store programs and program data to be used by the processor 1110. The RAM 1120 may temporarily store data transmitted from the host interface 1150 before transferring it to the storage medium 1200, and may temporarily store data transmitted from the storage medium 1200 before transferring it to the host device 1500.

The ROM 1130 may store program codes to be read by the processor 1110. The program codes may include commands to be processed by the processor 1110 for the processor 1110 to control the internal units of the controller 1100.

The ECC unit 1140 may encode data to be stored in the storage medium 1200, and may decode data read from the storage medium 1200. The ECC unit 1140 may detect and correct an error occurred in data, according to an ECC algorithm. The ECC unit 1140 may be configured in a manner substantially similar to the ECC unit 130 shown in FIG. 1.

The host interface 1150 may exchange data processing requests, data, etc. with the host device 1500.

The storage medium interface 1160 may transmit control signals and data to the storage medium 1200. The storage medium interface 1160 may be transmitted with data from the storage medium 1200. The storage medium interface 1160 may be coupled with the storage medium 1200 through a plurality of channels CHO to CHn.

The storage medium 1200 may include one or more nonvolatile memory devices NVM0 to NVMn. Each of the nonvolatile memory devices NVM0 to NVMn may be configured in a manner substantially the same as the nonvolatile memory device 200 shown in FIG. 1.

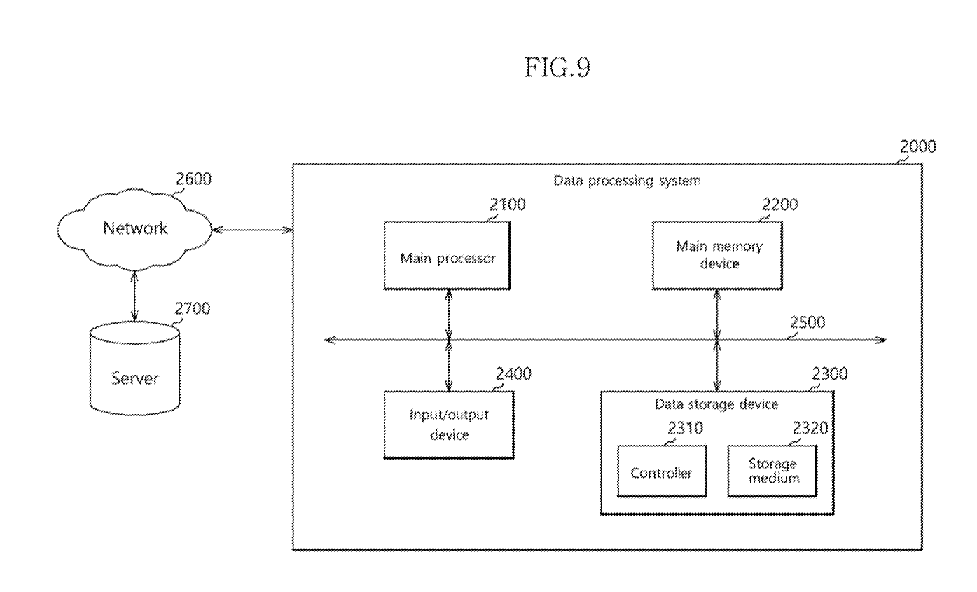

FIG. 9 illustrates a representation of an example of a data processing system 2000 to which the data storage device, according to an embodiment of the invention.

The data processing system 2000 may include a computer, a laptop, a netbook, a smart phone, a digital TV, a digital camera, a navigator, etc. The data processing system 2000 may include a main processor 2100, a main memory device 2200, a data storage device 2300, and an input/output device 2400. The internal units of the data processing system 2000 may exchange data, control signals, commands, user data and the like through a system bus 2500.

The main processor 2100 may control general operations of the data processing system 2000. The main processor 2100 may be, for example, a central processing unit such as a microprocessor. The main processor 2100 may execute the software programs of an operation system, an application, a device driver, and so forth, on the main memory device 2200.

The main memory device 2200 may store programs and program data to be used by the main processor 2100. The main memory device 2200 may temporarily store data to be transmitted to the data storage device 2300 and the input/output device 2400.

The data storage device 2300 may include a controller 2310 and a storage medium 2320. The data storage device 2300 may include any of the features of a data storage device as described herein.

The input/output device 2400 may include a monitor, a keyboard, a scanner, a touch screen, a mouse, and so forth, capable of exchanging data with a user, such as receiving a command for controlling the data processing system 2000 from the user or providing a processed result to the user.

According to an embodiment, the data processing system 2000 may communicate with at least one server 2700 through a network 2600 such as a local area network (LAN), a wide area network (WAN), a wireless network, and so on. The data processing system 2000 may include a network interface to access the network 2600.

While the invention has been described with reference to various embodiments of the invention, it will be understood to those skilled in the art that the invention may be practiced in many other variations and forms without departing from the spirit and scope of the invention as defined by the following claims.

What is claimed is:

1. A data storage device comprising:
a controller; and
a nonvolatile memory device comprising a memory region including a plurality of memory cells, the nonvolatile memory device being suitable for acquiring first data by applying a first read voltage to the plurality of memory cells and acquiring second data by applying a plurality of second read voltages to the plurality of memory cells, according to control of the controller,
wherein the controller is suitable for performing an error correction operation for the first data, based on the second data, and
wherein the plurality of second read voltages have nonlinear variation rates with respect to the first read voltage.

2. The data storage device according to claim 1, wherein intervals between the second read voltages decrease as they approach the first read voltage.

3. The data storage device according to claim 1, wherein the controller comprises:
a log likelihood ratio (LLR) generator suitable for generating a LLR values corresponding to the second data; and
an error correction code (ECC) unit suitable for performing the error correction operation for the first data, based on the LLR values.

4. The data storage device according to claim 1, wherein the controller is suitable for performing a pre-error correction operation for the first data before performing the error correction operation.

5. The data storage device according to claim 4, wherein the controller performs the pre-error correction operation in a decoding scheme different from the error correction operation.

6. The data storage device according to claim 1,
wherein the controller provides a plurality of offsets respectively corresponding to the variation rates, to the nonvolatile memory device and the nonvolatile memory device sets the plurality of second read voltages, based on the plurality of offsets.

7. The data storage device according to claim 1, wherein the error correction operation is performed based on low density parity check codes.

8. The data storage device according to claim 1, wherein, when the error correction operation fails, the controller adjusts one or more of the second read voltages, controls the nonvolatile memory device to acquire new second data by applying adjusted second read voltages to the memory cells, and iterates an error correction operation for the first data, based on the new second data.

9. The data storage device according to claim 8, wherein the controller adjusts the second read voltages to be more fine with respect to the first read voltage.

10. The data storage device according to claim 1, wherein the controller iterates an error correction operation by adjusting one or more of the second read voltages within a maximum adjustment count until the error correction operation succeeds.

11. A method for operating a data storage device, comprising:
acquiring first data by applying a first read voltage to memory cells;
acquiring second data by applying a plurality of second read voltages to the memory cells; and
performing an error correction operation for the first data based on the second data,
wherein the plurality of second read voltages have variation rates that are nonlinear with respect to the first read voltage.

12. The method according to claim 11, wherein intervals between the second read voltages decrease as they approach the first read voltage.

13. The method according to claim 11, wherein the performing of the error correction operation for the first data based on the second data further comprises:
generating LLR values corresponding to the second data; and
performing the error correction operation for the first data based on the LLR values.

14. The method according to claim 11, further comprising, before the performing of the error correction operation:
performing a pre-error correction operation for the first data and performing the error correction operation for the first data based on the second data only when the pre-error correction operation has failed.

15. The method according to claim 14, wherein the performing the pre-error correction operation comprises performing the pre-error correction operation in a decoding scheme different from the error correction operation.

16. The method according to claim 11, further comprising:
providing a plurality of offsets respectively corresponding to the variation rates, to the nonvolatile memory device; and
setting the plurality of second read voltages based on the plurality of offsets.

17. The method according to claim 11, wherein the error correction operation is performed based on low density parity check codes.

18. The method according to claim 11, wherein further comprising:
adjusting one or more of the second read voltages when the error correction operation has failed;
acquiring new second data by applying adjusted second read voltages to the memory cells; and
iterating an error correction operation for the first data, based on the new second data.

19. The method according to claim 18, wherein adjusting of the one or more of the second read voltages includes, the one or more of the second read voltages are adjusted to be more fine with respect to the first read voltage.

20. The method according to claim 18, wherein the adjusting of the one or more of the second read voltages, the acquiring of the new second data and the iterating of the error correction operation are iterated within a maximum adjustment count until the error correction operation succeeds.
